(19) United States
(12) Patent Application Publication
(10) Pub. No.: US 2006/0039120 A1
(43) Pub. Date: Feb. 23, 2006

(54) Expansion board for desktop personal computer

(76) Inventor: Sin Tae Young, Bala Cynwyd, PA (US)

Correspondence Address: APEX JURIS, PLLC, 13194 EDGEWATER LANE NORTHEAST, SEATTLE, WA, 98125, US

(21) Appl. No.: 11/205,589

(22) Filed: Aug. 15, 2005

(30) Foreign Application Priority Data
Aug. 17, 2004 (KR) 10-2004-64613

(51) Int. Cl. H05K 7/20; H05K 5/00

(52) U.S. Cl. 361/719

(57) ABSTRACT

An expansion board connected to an expansion slot of a main board of a desktop PC is provided. The expansion board has a plurality of components, including ICs, formed on its lower surface. The expansion board includes a PCB and a supporting member. A heat sink, a cooling fan, a plurality of components including ICs are formed on the PCB. The supporting member is connected to a predetermined portion of a case of the desktop PC to support the PCB. The expansion board is installed to the expansion slot such that the heat sink and the cooling fan are directed upward.

### BACKGROUND OF THE INVENTION

1. Field of the Invention

The present invention relates to an expansion board of a desktop personal computer, and particularly, to a graphic card mounted with a heat sink or a cooling fan. More particularly, the present invention relates to a graphic card having an improved installation structure of a heat sink or a cooling fan, thereby maximizing the cooling efficiency.

2. Description of the Related Art

Generally, the main body of a desktop personal computer (PC) has a case forming an external appearance, and the case includes various components such as a main board, a disk drive, a power supply, etc. The main body of a desktop PC is classified into various types, such as a small-sized type, a medium-sized type, and a large-sized type, depending on its size. Recently, the main body is becoming smaller so as to reduce the installation space of the PC system.

Generally, a copper leaf pattern for connecting a circuit device is formed on a surface of the main board, and various electronic components are attached on the main board.

Also, a socket for mounting a central processing unit (CPU) and a socket for mounting a memory module, and a plurality of expansion slots for mounting additional expansion boards are also attached on the main board. Here, additional card-type expansion boards are inserted and installed into the expansion slots. Generally, the expansion slots are classified into an accelerated graphics port (AGP) type, a peripheral component interconnection (PCI) type, and an industry standard architecture (ISA) type according to the type of a bus supported by a system circuit board.

Examples of the expansion boards include a graphic card, a sound card, and an LAN (local area network) card. The graphic card, the sound card and the LAN card are connected to the AGP expansion slot, the PCI expansion slot, and the ISA expansion slot, respectively.

The expansion board (such as the graphic card) includes a printed circuit board (PCB) having various components (such as integrated circuits (ICs)) formed thereon, and a supporting member for supporting and fixing the PCB to a predetermined portion of the PC case.

Recently, a heat sink and/or a cooling fan are/is installed over the ICs of the graphic card to dissipate heat generated from the ICs. The heat sink or the cooling fan is becoming larger with an increase in the amount of the heat generated from the ICs.

Generally, the expansion board (such as the graphic card) is inserted into the expansion slot and is thus connected to the main board in such a way that a PCB surface having various ICs formed thereon is directed toward a constant direction, for example, a downward direction.

In this case, the heat sink or the cooling fan becomes closer to the neighboring expansion board and thus the cooling efficiency thereof is greatly degraded.

Accordingly, there is required an improved installation structure of the heat sink or the cooling fan, which can provide a sufficient space therearound to maximize the cooling efficiency thereof.

### SUMMARY OF THE INVENTION

Accordingly, the present invention is directed to an expansion board of a desktop personal computer that substantially obviates one or more problems due to limitations and disadvantages of the related art.

An object of the present invention is to provide an expansion board of a desktop PC, which can provide a sufficient space around a heat sink or a cooling fan that is installed over ICs formed on a PCB of the expansion board, by improving the forming position of the ICs.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided an expansion slot of a main board of a desktop PC, the expansion board having a plurality of components, including ICs, formed on a lower surface thereof, the expansion board including: a PCB on which a heat sink, a cooling fan, a plurality of components including ICs are formed; and a supporting member connected to a predetermined portion of a case of the desktop PC to support the PCB, wherein the expansion board is installed to the expansion slot such that the heat sink and the cooling fan are directed upward.

Accordingly, a sufficient space can be provided around the heat sink or the cooling fan and thus the cooling efficiency thereof can be maximized.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a perspective view of an expansion board according to a first embodiment of the present invention;

FIG. 2 is a view illustrating a state where a plurality of the expansion boards according to the first embodiment are connected to expansion slots of a main board;

FIGS. 3 and 4 illustrates an expansion board according to a second embodiment of the present invention; and

FIG. 5 is a view illustrating a state where a plurality of the expansion boards according to the second embodiment are connected to expansion slots of a main board.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

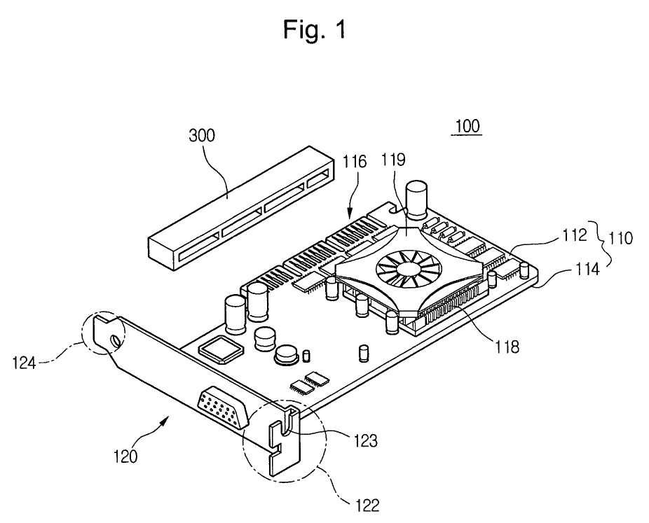

FIG. 1 is a perspective view of an expansion board according to a first embodiment of the present invention.

Referring to FIG. 1, an expansion board 100 includes a PCB 110 and a supporting member 120. Various components, such as ICs, are formed on the PCB 110. The supporting member 120 is fixed to a predetermined portion of a PC case to support the PCB 110. One end of the PCB 110 is connected to an expansion slot 300.

The supporting member 120 has a bent end portion 122 and a narrow end portion. A groove 123 is formed at the bent end portion 122, and the supporting member 120 is connected through the groove 123 to the PC case.

The ICs are formed on an upper surface 112 of the PCB 110, and a heat sink 118 and a cooling fan 119 are disposed over the ICs.

A slot tap 116 to be connected to the expansion slot 300 is formed at one edge of the PCB 110. When the slot tap 116 is connected to the expansion slot 300, the heat sink 118 and the cooling fan 119 are directed upward.

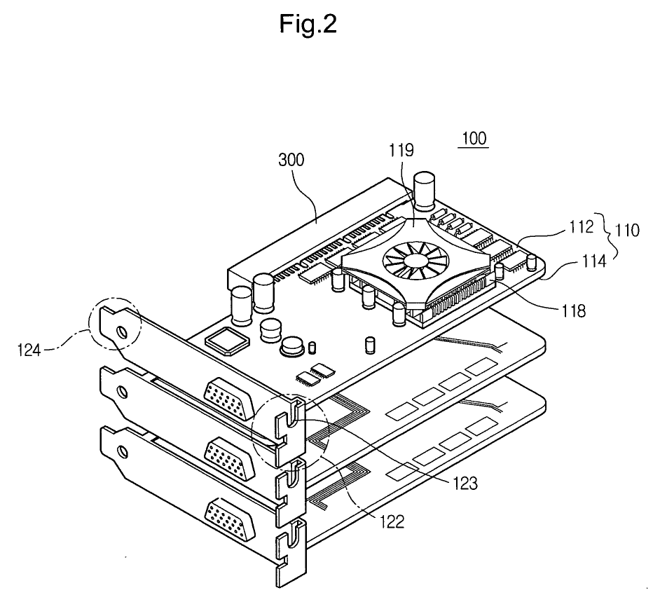

FIG. 2 is a view illustrating a state where a plurality of the expansion boards according to the first embodiment are connected to expansion slots of a main board.

Referring to FIG. 2, the expansion board 100 is connected to the expansion slot 300. At this time, the ICs, the heat sink 118, and the cooling fan 119 are directed upward.

Other expansion boards, such as a sound card and an LAN card, are installed under the expansion board 100 in such a way that their surfaces on which various components are formed are directed downward, that is, oppositely to the expansion board surface 112 on which the heat sink 118 and the cooling fan 18 are formed.

Accordingly, the heat sink 118 and the cooling fan 119 are not interfered with the various components formed on the other expansion boards, thereby enhancing the cooling efficiency.

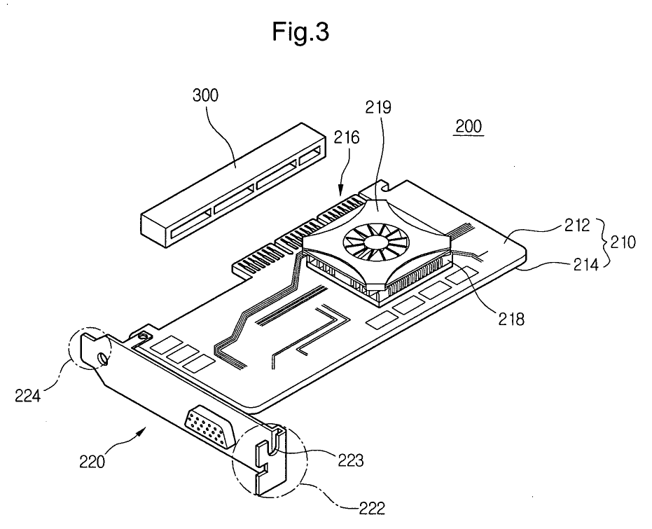

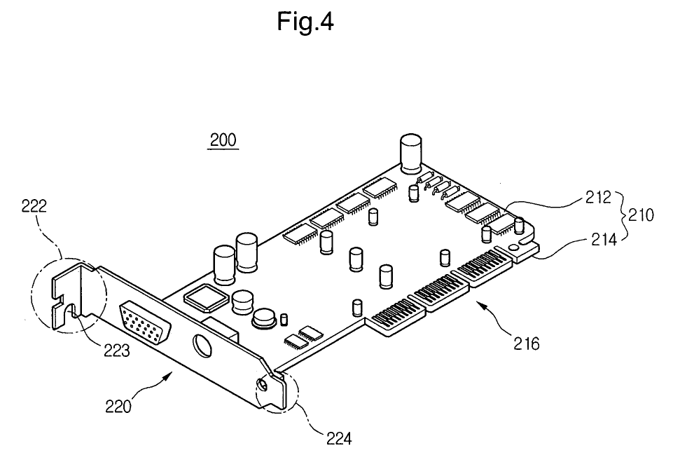

FIGS. 3 and 4 illustrates an expansion board according to a second embodiment of the present invention. FIG. 3 illustrates an upper surface of the expansion board, and FIG. 4 illustrates a lower surface of the expansion board.

Referring to FIGS. 3 and 4, an expansion board 200 includes a PCB 210 and a supporting member 220. Various components, such as ICs, are formed on the PCB 210. The supporting member 220 is fixed to a predetermined portion of a PC case to support the PCB 210. The second embodiment is different from the first embodiment in respect of the forming positions of the ICs, a heat sink 218, and a cooling fan 219.

In detail, the ICs, the heat sink 218, and the cooling fan 219 are formed on an upper surface 212 of the PCB 210, and other components are formed on a lower surface 214 of the PCB 210. Consequently, the ICs, the heat sink 218, and the cooling fan 219 are directed oppositely to the other components formed on the lower surface 214.

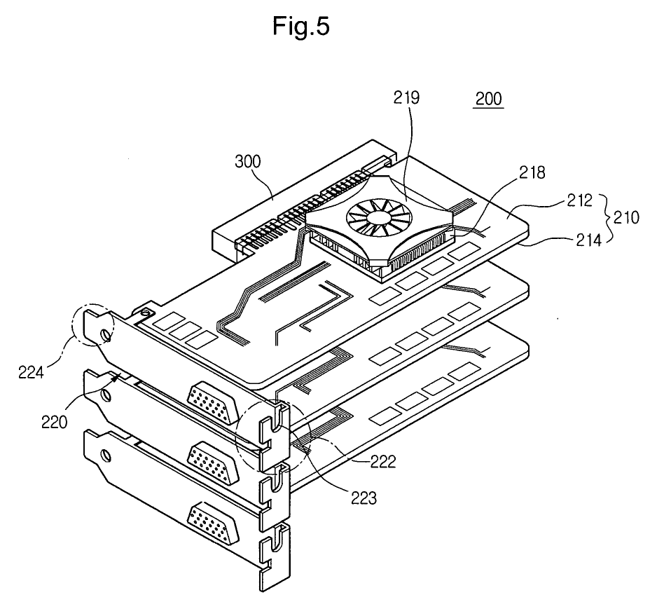

FIG. 5 is a view illustrating a state where a plurality of the expansion boards according to the second embodiment are connected to expansion slots of a main board.

Referring to FIG. 5, the expansion board 200 is connected to the expansion slot 300. At this time, the ICs, the heat sink 218, and the cooling fan 219 are directed upward while the other components are directed downward.

Other expansion boards, such as a sound card and an LAN card, are installed under the expansion board 200 in such a way that their surfaces on which various components are formed are directed downward, that is, oppositely to the upper surface 212 on which the heat sink 118 and the cooling fan 18 are formed.

Accordingly, more space is provided around the heat sink 218 and the cooling fan 219, thereby maximizing the cooling efficiency.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An expansion board connected to an expansion slot of a main board of a desktop PC, the expansion board having a plurality of components, including ICs, formed on a lower surface thereof, the expansion board comprising:
a PCB on which a heat sink, a cooling fan, a plurality of components including ICs are formed; and
a supporting member connected to a predetermined portion of a case of the desktop PC to support the PCB,
wherein the expansion board is installed to the expansion slot such that the heat sink and the cooling fan are directed upward.

2. The expansion board according to claim 1, wherein the heat sink and the cooling fan are formed on an upper surface of the PCB

3. The expansion board according to claim 1, wherein the components are formed on a surface identical to a surface on which the heat sink and the cooling fan are formed.

4. The expansion board according to claim 1, wherein the components are formed on a surface opposite to a surface on which the heat sink and the cooling fan are formed.

5. The expansion board according to claim 1, wherein the expansion board and the expansion slot are provided in plurality, and the plurality of expansion boards are respectively connected to the plurality of expansion slots such that surfaces of the expansion boards, on which the components are formed, are directed in the same direction.

6. The expansion board according to claim 1, wherein the expansion board is connected to the expansion slot such that a surface of the expansion board, on which the components are formed, is directed upward.

7. The expansion board according to claim 1, wherein the expansion board is connected to the expansion slot such that a surface of the expansion board, on which the components are formed, is directed downward.

8. The expansion board according to claim 1, wherein the expansion board is a graphic card.

9. An expansion board connected to a main board of a desktop PC such that a plurality of components formed thereon are directed downward, the expansion board comprising:
a PCB including a slot tap inserted into an expansion slot of the main board and an upper surface on which a heat sink or a cooling fan is formed; and
a supporting member including a first bent end portion and a second narrow end portion, the first bent portion having a groove formed at an upper side thereof.

10. The expansion board according to claim 9, wherein a plurality of components including ICs are formed on the upper surface of the PCB.

11. The expansion board according to claim 9, wherein the expansion board is connected to main board such that the heat sink and the cooling fan are directed upward.

12. An expansion board connected to an expansion slot of a main board of a desktop PC, the expansion board having a plurality of components, including los, formed on a lower surface thereof, the expansion board comprising:
a PCB having one surface on which non-IC components are formed and the other surface on which ICs, a heat sink, and a cooling fan are formed; and
a supporting member connected to a predetermined portion of a case of the desktop PC to support the PCB.

13. The expansion board according to claim 12, wherein the heat sink and the cooling fan are formed on an upper surface of the PCB

14. The expansion board according to claim 12, wherein the expansion board is installed to the main board such that the heat sink and the cooling fan are directed upward.

15. The expansion board according to claim 12, wherein the expansion board and the expansion slot are provided in plurality, and the plurality of expansion boards are respectively connected to the plurality of expansion slots such that surfaces of the expansion boards, on which the components are formed, are directed in the same direction.
